(19) United States
(12) Patent Application Publication
(10) Pub. No.: US 2016/0181574 A1
(43) Pub. Date: Jun. 23, 2016

(54) METHOD FOR MANUFACTURING FLEXIBLE OLED (ORGANIC LIGHT EMITTING DIODE) PANEL

(71) Applicant: Shenzhen China Star Optoelectronics Technology Co., Ltd., Shenzhen (CN)

(72) Inventors: Weijing ZENG, Shenzhen (CN); Chihche LIU, Shenzhen (CN)

(73) Assignee: Shenzhen China Star Optoelectronics Technology Co., Ltd., Shenzhen (CN)

(21) Appl. No.: 15/055,663

(22) Filed: Feb. 29, 2016

Related U.S. Application Data
(63) Continuation-in-part of application No. 14/241,072, filed on Feb. 25, 2014.

(51) Int. Cl. H01L 51/56; H01L 51/50

(52) U.S. Cl. CPC H01L 51/56; H01L 51/5056; H01L 2251/5338

(57) ABSTRACT

A method for manufacturing the flexible OLED panel includes: (1) providing a rigid substrate and a flexible substrate; (2) forming a metal layer on a circumference of the rigid substrate; (3) forming a support layer inboard the metal layer; (4) positioning the flexible substrate on the rigid substrate; (5) applying a voltage to the metal layer to heat the flexible substrate so as to make the material of the flexible substrate in contact with the metal layer reach a melt point for bonding the flexible substrate and the rigid substrate together; (6) forming an OLED device on the flexible substrate and packaging the OLED device; and (7) applying a voltage to the metal layer to heat the flexible substrate, so that after the material of the flexible substrate in contact with and the metal layer reaches the melt point, the flexible substrate and the rigid substrate are separated.

### CROSS REFERENCE TO RELATED APPLICATIONS

The application is a continuation-in-part of the co-pending U.S. patent application Ser. No. 14/241,072 filed on Feb. 25, 2014.

### BACKGROUND OF THE INVENTION

1. Field of the Invention

The present invention relates to the field of flat panel displaying, and in particular to a method for manufacturing a flexible OLED (Organic Light Emitting Diode) panel.

2. the Related Arts

A flat display device has various advantages, such as thin device body, low power consumption, and being free of radiation, and is thus of wide applications. The flat display devices that are currently available include liquid crystal displays (LCDs) and organic electroluminescence devices (OELDs), which are also referred to as organic light emitting diodes (OLEDs).

The known liquid crystal displays are generally backlighting liquid crystal displays, which include an enclosure, a liquid crystal display panel arranged in the enclosure, and a backlight module mounted inside the enclosure. The principle of operation of the liquid crystal display panel is that liquid crystal molecules are interposed between two parallel glass substrates and a driving voltage is applied to the glass substrates to control the rotation of the liquid crystal molecules so as to refract out the light from the backlight module to form an image.

Referring to FIG. 1, the conventional liquid crystal display panel generally comprises: a thin-film transistor (TFT) substrate 302, a color filter (CF) substrate 304 that is laminated on the thin-film transistor substrate 302, and a liquid crystal layer 306 arranged between the thin-film transistor substrate 302 and the color filter substrate 304. The thin-film transistor substrate 302 drives the liquid crystal molecules contained in the liquid crystal layer 306 to rotate in order to display a corresponding image.

The organic electroluminescence devices have various advantages over the liquid crystal displays, such as being fully solid state, active emission of light, high brightness, high contrast, being ultra thin, low cost, low power consumption, fast response, wide view angle, wide range of operation temperature, and being capable of flexible displaying. The structure of an organic electroluminescent diode generally comprises a substrate, an anode, a cathode, and an organic function layer and the principle of light emission thereof is that multiple layers of organic materials that are of extremely small thickness is formed between the anode and the cathode through vapor deposition, whereby positive and negative carriers, when injected into the organic semiconductor films, re-combine with each other to generate light. The organic function layer of the organic light emitting diode is generally made up of three function layers, which are respectively a hole transport layer (HTL), an emissive layer (EML), and an electron transport layer (ETL). Each of the function layers can be a single layer or more than one layer. For example, the hole transport layer may sometimes be further divided into a hole injection layer and a hole transport layer and the electron transport layer may also be divided into an electron transport layer and an electron injection layer. However, they are of substantially the same function and are thus collectively referred to as the hole transport layer and the electron transport layer.

Currently, the manufacture of a full-color organic electroluminescence device is generally done with three methods, which are RGB juxtaposition and individual emission method, white light in combination with color filter method, and color conversion method, among which the RGB juxtaposition and individual emission method is most promising and has the most practical applications. The manufacturing method thereof is that red, green, and blue use different host and guest light-emitting materials.

The development of the organic light emitting diode brings in the displaying technology of flexible organic electroluminescent diode as a new technique of the panel industry. However, a flexible substrate is susceptible to deformation, making it hard to handle in a manufacture process, particularly for the process of alignment or formation of film of thin-film transistor (TFT) or OLED.

### SUMMARY OF THE INVENTION

An object of the present invention is to provide a method for manufacturing a flexible OLED (Organic Light Emitting Diode) panel, which comprises a simplified manufacture process, does not cause damage of an OLED element, and can realize automatization to thereby improve the manufacturing efficiency.

To achieve the above objects, the present invention provides a method for manufacturing an OLED panel, which comprises the following steps:

(1) providing a rigid substrate a the flexible substrate;

(2) forming a metal layer on a circumference of the rigid substrate;

(3) forming a support layer on the rigid substrate inboard the metal layer;

(4) positioning the flexible substrate on the rigid substrate;

(5) applying an electrical voltage to the metal layer to subject the flexible substrate to heating to make material of the flexible substrate that is in contact with the metal layer reach a melt point and then terminating heating to allow the flexible substrate and the rigid substrate to bond together;

(6) forming an OLED device on the flexible substrate and subjecting the OLED device to packaging; and

(7) applying an electrical voltage to the metal layer to subject the flexible substrate to heating to make the material of the flexible substrate that is in contact with the metal layer reach the melt point and separating the flexible substrate and the rigid substrate so as to obtain a flexible OLED panel.

The rigid substrate is a glass substrate.

The support layer has an upper surface that is substantially flush with an upper surface of the metal layer.

The metal layer is made of a metal of large resistivity.

The metal layer is made of iron, zinc, or chromium.

The support layer is made of silicon oxide or silicon nitride.

In step (4), under a vacuum condition, the flexible substrate is laid flat on the rigid substrate by using a roller to be attached thereto by means of vacuum.

The OLED device comprises an anode formed on the flexible substrate, an organic function layer formed on the anode, and a cathode formed on the organic function layer.

The organic function layer comprises a hole transport layer formed on the anode, an organic emissive layer formed on the hole transport layer, and an electron transport layer formed on the organic emissive layer.

Step (7) comprises having the flexible substrate held by vacuum suction and mechanically raised to realize separation of the flexible substrate and the rigid substrate.

The present invention also provides a method for manufacturing a flexible OLED panel, which comprises the following steps:

(1) providing a rigid substrate and a flexible substrate;

(2) forming a metal layer on a circumference of the rigid substrate;

(3) forming a support layer on the rigid substrate inboard the metal layer;

(4) positioning the flexible substrate on the rigid substrate;

(5) applying an electrical voltage to the metal layer to subject the flexible substrate to heating to make material of the flexible substrate that is in contact with the metal layer reach a melt point and then terminating heating to allow the flexible substrate and the rigid substrate to bond together;

(6) forming an OLED device on the flexible substrate and subjecting the OLED device to packaging; and

(7) applying an electrical voltage to the metal layer to subject the flexible substrate to heating to make the material of the flexible substrate that is in contact with the metal layer reach the melt point and separating the flexible substrate and the rigid substrate so as to obtain a flexible OLED panel;

wherein the rigid substrate is a glass substrate;

wherein the support layer has an upper surface that is substantially flush with an upper surface of the metal layer;

wherein the metal layer is made of a metal of large resistivity;

wherein the metal layer is made of iron, zinc, or chromium; and

wherein the support layer is made of silicon oxide or silicon nitride.

In step (4), under a vacuum condition, the flexible substrate is laid flat on the rigid substrate by using a roller to be attached thereto by means of vacuum.

The OLED device comprises an anode formed on the flexible substrate, an organic function layer formed on the anode, and a cathode formed on the organic function layer.

The organic function layer comprises a hole transport layer formed on the anode, an organic emissive layer formed on the hole transport layer, and an electron transport layer formed on the organic emissive layer.

Step (7) comprises having the flexible substrate held by vacuum suction and mechanically raised to realize separation of the flexible substrate and the rigid substrate.

The efficacy of the present invention is that the present invention provides a method for manufacturing a flexible OLED panel, in which a metal layer having a large electrical resistivity is formed along a circumference of a rigid substrate and a non-adhering support layer is provided in the middle. The flexible substrate and the rigid substrate are subjected to heating by applying electricity to the circumferentially arranged metal layer to bond together in order to obtain a flat and handleable flexible substrate. After processes of film formation of TFT and OLED and packaging are carried out and completed, electricity is applied again the bonded portion of the flexible substrate and the rigid substrate and a mechanical force is applied to have the flexible substrate and the rigid substrate separated. This process is simple and allow the OLED device to be effectively protected without being damaged and also enables automatized manufacture to effectively enhance manufacturing performance and reduce manufacturing cost.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view showing the structure of a conventional liquid crystal display panel;

FIG. 2 is a flow chart illustrating a method for manufacturing a flexible OLED (Organic Light Emitting Diode) panel according to the present invention; and

FIGS. 3-6 illustrates the process of the method for manufacturing an OLED panel according to the present invention.

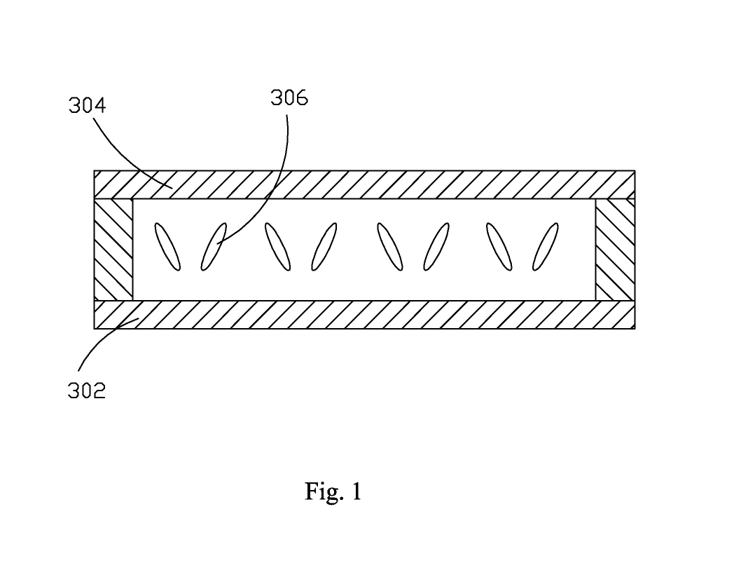

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

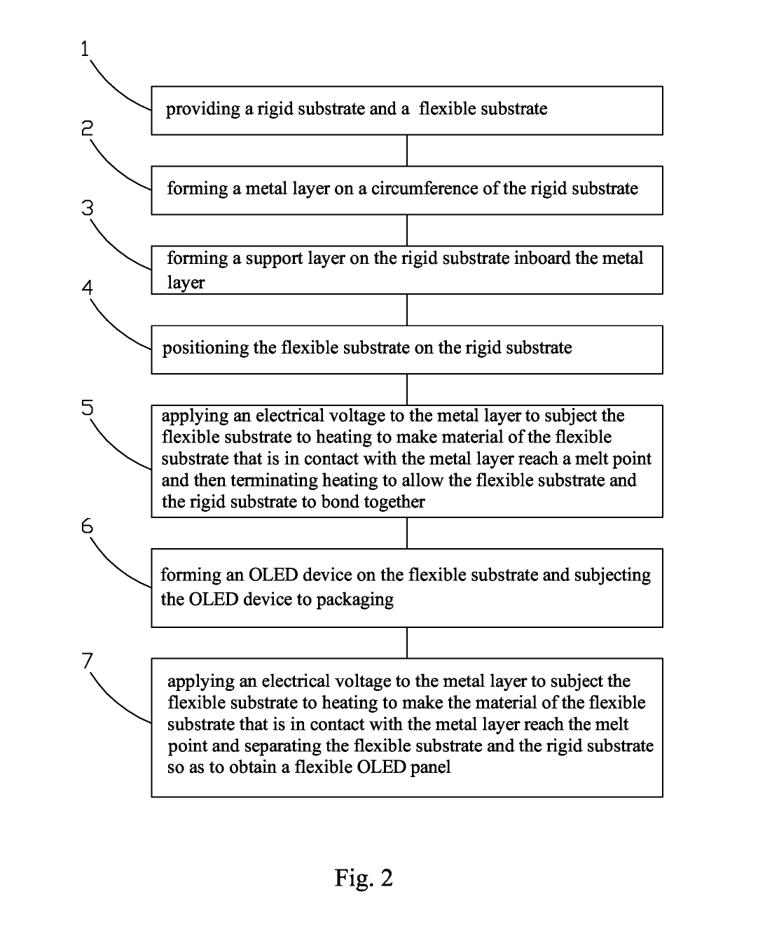

Referring to FIG. 2, the present invention provides a method for manufacturing a flexible OLED (Organic Light Emitting Diode) panel, which comprises the following steps:

Step 1: providing a rigid substrate 20 and a flexible substrate 40.

In the instant embodiment, the rigid substrate 20 is a glass substrate.

Step 2: forming a metal layer 22 on a circumference of the rigid substrate 20.

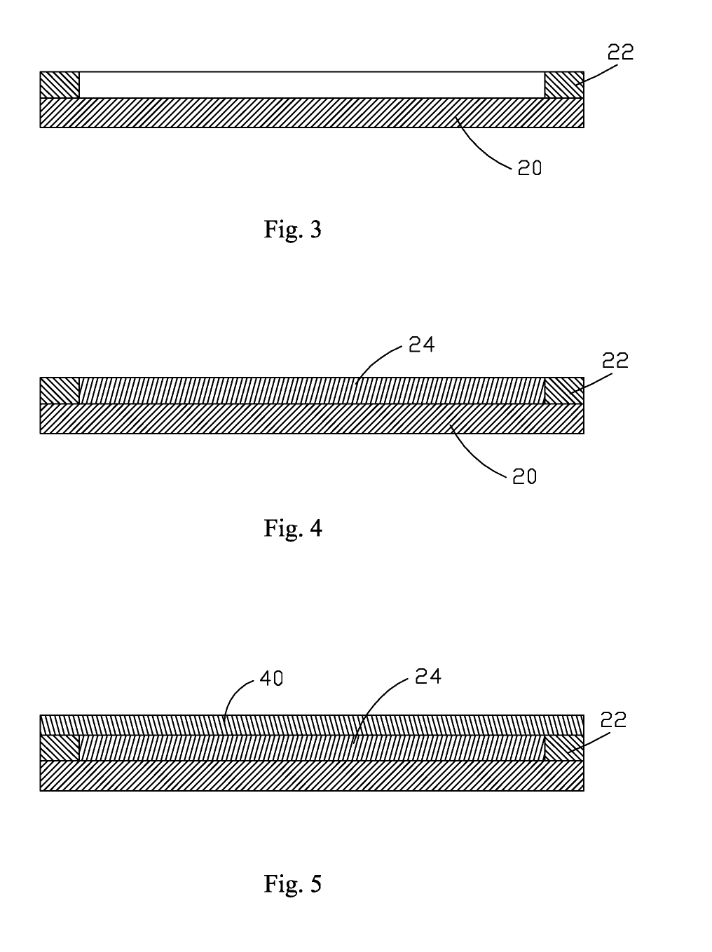

Referring to FIG. 3, the metal layer 22 is formed along a circumferential edge of the rigid substrate 20. In an example that the rigid substrate 20 is a rectangular plate, the metal layer 22 is formed on a surface of the rectangular plate and co-extensive with four edges of the plate. The metal layer 22 is made of a large resistivity metal. Under the condition of identical width, thickness, and length, the larger the electric resistivity of a metal possesses, the larger the electrical resistance of the metal will be; and the larger the electrical resistance of the metal has, the greater of the amount of heat generated by the metal will be when electricity is applied thereto, so that the time of heating can be shortened. The large resistivity metal can be metal iron (Fe), zinc (Zn) or chromium (Cr).

Step 3: forming a support layer 24 on the rigid substrate 20 inboard the metal layer 22.

Referring to FIG. 4, the support layer 24 is formed on the rigid substrate 20 in such a way that the support layer 24 is located inboard the metal layer 22. The support layer 24 is made of silicon oxide (SiO) or silicon nitride (SiN) in such a way that an upper surface of the support layer 24 is substantially flush with an upper surface of the metal layer 22 to ensure flatness of the flexible substrate 40 that is laid flat on the support layer 24 and the metal layer 22. Preferably, the support layer 24 is completely filled up an internal cavity delimited by the metal layer 22 and the surface of the substrate 20 on which the metal layer 22 is formed.

Step 4: positioning the flexible substrate 40 on the rigid substrate 20.

The flexile substrate 40 is preferably laid flat and supported by the support layer 24 and the metal layer 22 so that a circumferential edge portion of the flexible substrate 40 is supported on and in direct contact with the metal layer, while a central portion that is surrounded by the circumferential edge portion is supported on the support layer 24 and is not in contact with metal layer 22. The central portion of the flexible substrate 40 is thus spaced from the metal layer 22.

Referring to FIG. 5, under a vacuum condition, the flexible substrate 40 is laid flat on the rigid substrate 20 by using a roller (not shown) to be attached thereto by means of vacuum.

Step 5: applying an electrical voltage to the metal layer 22 to subject the flexible substrate 40 to heating to make material of the flexible substrate 40 that is in contact with the metal layer 22 reach a melt point and then terminating heating to allow the flexible substrate 40 and the rigid substrate 20 to bond together.

The electricity applied to the metal layer 22 is converted by the resistivity of the metal layer 22 into heat so as to generate heat in the metal layer 22. The heat is transferred directly to a portion of the flexible layer 22 in direct contact therewith, such as the circumferential portion of the flexible layer 22 that is supported on the metal layer 22. The heat so transferred to the flexible substrate 40 increases the temperature of the portion of the flexible layer 40 in direct contact with the metal layer 22 to the melting point, leading to melting of the portion of the flexible substrate 40, while the other portion of the flexible substrate 40, such as the central portion or at least a part thereof, that is spaced from the metal layer 22 is kept below the melting point and is not molten.

Once the application of electricity and heating applied to the metal layer is terminated, the molten portion of the flexible substrate 40 gets cooled down and solidified again thereby securely bonded to the metal layer 22 and thus attached to the rigid substrate 20. This makes the flexible substrate 20, the metal layer 22, the support layer 24, and the rigid substrate 40 fixed together through the bonding between the portion of the flexible substrate 40 that has been molten and re-solidifies and the metal layer 22 (and the rigid substrate 20).

Step 6: forming an OLED device 42 on the flexible substrate 40 and subjecting the OLED device 42 to packaging.

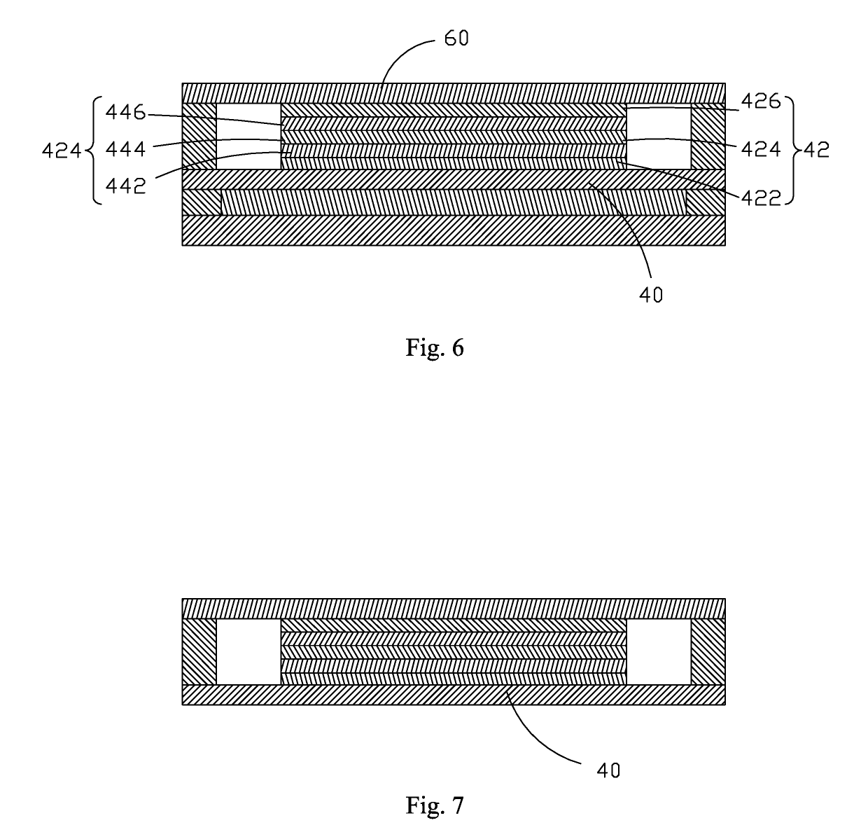

Referring to FIG. 6, the OLED device 42 comprises an anode 422 formed on the flexible substrate 40, an organic function layer 424 formed on the anode 422, and a cathode 426 formed on the organic function layer 424. More specifically, the organic function layer 424 comprises a hole transport layer 442 formed on the anode 422, an organic emissive layer 444 formed on the hole transport layer 442, and an electron transport layer 446 formed on the organic emissive layer 444. The OLED device 42 is preferably formed on the central portion of the flexible substrate 40 that is supported by the support layer 24 and is not contact with and thus spaced from the metal layer 22.

To package, a package lid 60 is provided and the package lid 60 is laminated to the flexible substrate 40 by applying a UV resin or a glass cement so as to hermetically seal the OLED device between the package lid 60 and the flexible substrate 40.

Step 7: applying an electrical voltage to the metal layer 22 to subject the flexible substrate 40 to heating to make the material of the flexible substrate 40 that is in contact with the metal layer 22 reach the melt point and separating the flexible substrate 40 and the rigid substrate 20 so as to obtain a flexible OLED panel.

Referring to FIG. 7, specifically, electricity is applied to the metal layer 22 and the metal layer 22 gets heated again to have the portion of the flexible substrate 40 that is in direct contact with (and bonded to) the metal frame 22 molten. For example, the circumferential edge portion of the flexible substrate 40 that is supported on the metal layer 22 would directly receive heat from the metal layer 22 and may reach a temperature higher than the melting point thereof so as to get molten. This makes the flexible substrate 40 no long securely bonded to the metal layer 22 and may be separated therefrom. Afterwards, the flexible substrate 40 is held by means of vacuum suction and is mechanically raised to separate the flexible substrate 40 from the rigid substrate 20 and thus obtaining the flexible OLED panel.

It is noted that it is possible to first form a thin-film transistor (TFT) on the flexible substrate 20 and then forming the OLED device 40 on the thin-film transistor to make an active-matrix organic light emitting diode (AMOLED), in which the thin-film transistor can be manufactured by using any known techniques of which unnecessary description is omitted herein.

In summary, the present invention provides a method for manufacturing a flexible OLED panel, in which a metal layer having a large electrical resistivity is formed along a circumference of a rigid substrate and a non-adhering support layer is provided in the middle. The flexible substrate and the rigid substrate are subjected to heating by applying electricity to the circumferentially arranged metal layer to bond together in order to obtain a flat and handleable flexible substrate. After processes of film formation of TFT and OLED and packaging are carried out and completed, electricity is applied again the bonded portion of the flexible substrate and the rigid substrate and a mechanical force is applied to have the flexible substrate and the rigid substrate separated. This process is simple and allow the OLED device to be effectively protected without being damaged and also enables automatized manufacture to effectively enhance manufacturing performance and reduce manufacturing cost.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing a flexible OLED (Organic Light Emitting Diode) panel, comprising the following steps:
(1) providing a rigid substrate and a flexible substrate;
(2) forming a metal layer that is formed of a metal of large resistivity on a circumference of the rigid substrate;
(3) forming a support layer on the rigid substrate inboard the metal layer;
(4) positioning the flexible substrate on the rigid substrate in such a way that the flexible substrate is laid flat on and supported by the support layer and the metal layer with a first portion of the flexible substrate in direct contact with and supported by the metal layer, while a remaining, second portion of the flexible substrate is not in contact with the metal layer and is supported by the support layer;
(5) applying an electrical voltage to the metal layer to generate heat directly applied to and thus subject the first portion of the flexible substrate to heating to make the first portion of the flexible substrate that is in direct contact with the metal layer reach a melt point and get molten and then terminating heating to allow the molten first portion of the flexible substrate to bond to the metal layer and thus attach to the rigid substrate, wherein the flexible substrate is directly bonded to the metal layer and attached to the rigid substrate via the metal layer;
(6) forming an OLED device on the second portion of the flexible substrate and subjecting the OLED device to packaging; and
(7) applying an electrical voltage to the metal layer to subject the first portion of the flexible substrate to heating to make the first portion of the flexible substrate that is in bonded to the metal layer reach the melt point and get molten again for separating the flexible substrate and the rigid substrate from each other so as to obtain a flexible OLED panel.

2. The method as claimed in claim 1, wherein the rigid substrate is a glass substrate.

3. The method as claimed in claim 1, wherein the support layer has an upper surface that is substantially flush with an upper surface of the metal layer.

4. The method as claimed in claim 1, wherein the metal layer is formed of iron, zinc, or chromium.

5. The method as claimed in claim 1, wherein the support layer is made of silicon oxide or silicon nitride.

6. The method as claimed in claim 1, wherein in step (4), under a vacuum condition, the flexible substrate is laid flat on the rigid substrate by using a roller to be attached thereto by means of vacuum.

7. The method as claimed in claim 1, wherein the OLED device comprises an anode formed on the flexible substrate, an organic function layer formed on the anode, and a cathode formed on the organic function layer.

8. The method as claimed in claim 7, wherein the organic function layer comprises a hole transport layer formed on the anode, an organic emissive layer formed on the hole transport layer, and an electron transport layer formed on the organic emissive layer.

9. The method as claimed in claim 1, wherein step (7) comprises having the flexible substrate held by vacuum suction and mechanically raised to separate the flexible substrate from the rigid substrate.

10. A method for manufacturing a flexible OLED (Organic Light Emitting Diode) panel, comprising the following steps:
(1) providing a rigid substrate and a flexible substrate;
(2) forming a metal layer that is formed of a metal of large resistivity on a circumference of the rigid substrate;
(3) forming a support layer on the rigid substrate inboard the metal layer;
(4) positioning the flexible substrate on the rigid substrate in such a way that the flexible substrate is laid flat on and supported by the support layer and the metal layer with a first portion of the flexible substrate in direct contact with and supported by the metal layer, while a remaining, second portion of the flexible substrate is not in contact with the metal layer and is supported by the support layer;
(5) applying an electrical voltage to the metal layer to generate heat directly applied to and thus subject the first portion of the flexible substrate to heating to make the first portion of the flexible substrate that is in direct contact with the metal layer reach a melt point and get molten and then terminating heating to allow the molten first portion of the flexible substrate to bond to the metal layer and thus attach to the rigid substrate, wherein the flexible substrate is directly bonded to the metal layer and attached to the rigid substrate via the metal layer;
(6) forming an OLED device on the second portion of the flexible substrate and subjecting the OLED device to packaging; and
(7) applying an electrical voltage to the metal layer to subject the first portion of the flexible substrate to heating to make the first portion of the flexible substrate that is in bonded to the metal layer reach the melt point and get molten again for separating the flexible substrate and the rigid substrate from each other so as to obtain a flexible OLED panel;
wherein the rigid substrate is a glass substrate;
wherein the support layer has an upper surface that is substantially flush with an upper surface of the metal layer;
wherein the metal layer is formed of iron, zinc, or chromium; and
wherein the support layer is made of silicon oxide or silicon nitride.

11. The method as claimed in claim 10, wherein in step (4), under a vacuum condition, the flexible substrate is laid flat on the rigid substrate by using a roller to be attached thereto by means of vacuum.

12. The method as claimed in claim 10, wherein the OLED device comprises an anode formed on the flexible substrate, an organic function layer formed on the anode, and a cathode formed on the organic function layer.

13. The method as claimed in claim 12, wherein the organic function layer comprises a hole transport layer formed on the anode, an organic emissive layer formed on the hole transport layer, and an electron transport layer formed on the organic emissive layer.

14. The method as claimed in claim 10, wherein step (7) comprises having the flexible substrate held by vacuum suction and mechanically raised to separate the flexible substrate from the rigid substrate.
